(19) United States
(12) Patent Application Publication
(10) Pub. No.: US 2006/0000704 A1
(43) Pub. Date: Jan. 5, 2006

(54) Solution treatment apparatus and solution treatment method

(75) Inventors: Hiroshi Sato, Yamanashi (JP); Gishi Chung, Yamanashi (JP)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/530,678

(22) PCT Filed: Jun. 4, 2003
(86) PCT No.: PCT/JP03/07096

§ 371 Date: Apr. 8, 2005

(30) Foreign Application Priority Data
Oct. 8, 2002 (JP) 2002-294805

(51) Int. Cl. C23C 14/00

(52) U.S. Cl. 204/192.1

(57) ABSTRACT

A solution treatment apparatus of the present invention includes a diaphragm position varying mechanism configured to partly vary the position of a diaphragm. According to the solution treatment apparatus of the present invention, partial positional change of the diaphragm is possible. Therefore, uniformity of solution treatment in a surface of a substrate can be effectively improved.

### TECHNICAL FIELD

The present invention relates to a solution treatment apparatus and a solution treatment method for applying solution treatment on a substrate.

### BACKGROUND ART

The recent improvement in integration degree of semiconductor devices has promoted the utilization of a buried wiring method in which wiring is formed by burying metal in wiring trenches or connection holes formed in a semiconductor wafer (hereinafter, simply referred to as a “wafer”). This has given rise to a strong demand for the development of a deposition apparatus having a high burying speed. Currently, an electrolytic plating apparatus has been drawing attention as a deposition apparatus satisfying such a demand.

In the electrolytic plating apparatus, a wafer is immersed in a plating solution in a plating solution tank and a voltage is applied between anode electrodes and cathode electrodes that are in contact with a periphery portion of the wafer, thereby burying plating.

However, electricity is supplied from the periphery portion of the wafer in such an electrolytic plating apparatus, so that the wafer has a larger current density in the periphery portion than in a center portion, which poses a problem of low plating uniformity in a surface.

At present, as one method of solving the above-described problem, Japanese Patent Laid-Open Application No. 2000-87285 and Japanese Patent Laid-Open Application No. 2000-96282 disclose a method of controlling the current density by disposing a movable shielding plate in a plating solution tank and moving the shielding plate during a plating process.

In the above-described method, however, since the shielding plate changes the flow of the plating solution, uniformity of flow velocity distribution is deteriorated, which poses such a problem that plating uniformity in the surface cannot be effectively improved. Note that this problem is a problem resulting from the disposition of the shielding plate and thus is a problem also arising when the shielding plate is not moved during the plating process.

### DISCLOSURE OF THE INVENTION

The present invention is made to solve the problems stated above. Therefore, the object thereof is to provide a solution treatment apparatus and a solution treatment method capable of effectively improving uniformity of solution treatment in a surface of a substrate.

A solution treatment apparatus according to an aspect of the present invention includes: a treatment solution tank configured to store a treatment solution in which a substrate is to be immersed; a first electrode in electrical contact with the substrate immersed in the treatment solution; a second electrode disposed in the treatment solution tank, a voltage being applied between the second electrode and the first electrode; a diaphragm disposed between the substrate and the second electrode; and a diaphragm position varying mechanism configured to partly vary a position of the diaphragm. The solution treatment apparatus according to this invention has the diaphragm position varying mechanism, so that the position of the diaphragm is partly variable. This enables effective improvement in uniformity of solution treatment in a surface of the substrate.

It is preferable that, in a state before the position of the diaphragm is partly varied, a portion of the diaphragm facing a center portion of the substrate is positioned closer to a substrate side than a portion of the diaphragm facing a periphery portion of the substrate. The use of such a diaphragm can facilitate effective improvement in uniformity of solution treatment in a surface of the substrate.

The diaphragm position adjusting mechanism preferably moves a portion of the diaphragm facing a center portion of the substrate. The movement of such a portion can facilitate partly changing the position of the diaphragm.

It is preferable to further provide a controller configured to control the diaphragm position varying mechanism. When the controller is provided, the diaphragm position adjusting mechanism can be automatically controlled.

It is preferable that the solution treatment apparatus further includes a sensor configured to partly measure a degree of solution treatment applied on the substrate, and that the controller controls the diaphragm position varying mechanism based on a result of the measurement by the sensor. The provision of the sensor and such control by the controller enable more effective improvement in uniformity of solution treatment in a surface of the substrate.

It is preferable that the solution treatment apparatus further includes a measurement substrate having a plurality of electrodes and an ammeter configured to measure a current passing through each of the electrodes, and that the controller controls the diaphragm position varying mechanism based on a result of the measurement by the ammeter. The provision of the measurement substrate and such control by the controller enable more effective improvement in uniformity of solution treatment in a surface of the substrate.

A solution treatment apparatus according to another aspect of the present invention includes: a treatment solution tank configured to store a treatment solution in which a substrate is to be immersed; a first electrode in electrical contact with the substrate immersed in the treatment solution; a second electrode disposed in the treatment solution tank, a voltage being applied between the first electrode and the second electrode; and a diaphragm disposed between the substrate and the second electrode, a portion of the diaphragm facing a center portion of the substrate being positioned closer to a substrate side than a portion of the diaphragm facing a periphery portion of the substrate. The solution treatment apparatus according to this invention has such a diaphragm, which enables effective improvement in uniformity of solution treatment in a surface of the substrate.

A solution treatment method according to still another aspect of the present invention includes: immersing a substrate in a treatment solution in a treatment solution tank and passing a current through the immersed substrate to apply solution treatment on the substrate; and partly measuring a degree of the solution treatment applied on the substrate while the solution treatment is being applied on the substrate, and partly varying a position of a diaphragm disposed in the treatment solution tank based on a result of the measurement, to adjust the degree of the solution treatment in the substrate. The solution treatment method of this invention thus adjusts the degree of the solution treatment, which enables effective improvement in uniformity of solution treatment in a surface of the substrate.

A solution treatment method according to yet another aspect of the present invention includes: immersing a measurement substrate having a plurality of electrodes in a treatment solution in a treatment solution tank and passing a current through each of the electrodes of the immersed measurement substrate to apply solution treatment on the measurement substrate while measuring the current passing through each of the electrodes; immersing a substrate in the treatment solution in the treatment solution tank and passing a current through the immersed substrate to apply solution treatment on the substrate; and partly varying a position of a diaphragm disposed in the treatment solution tank based on a result of the measurement while the solution treatment is being applied on the substrate, to adjust a degree of the solution treatment in the substrate. The solution treatment method according to this invention thus adjusts the degree of the solution treatment, which enables effective improvement in uniformity of solution treatment in a surface of the substrate.

### BRIEF DESCRIPTION OF DRAWINGS

FIG. 1 is a schematic vertical sectional view of an electrolytic plating apparatus according to a first embodiment.

FIG. 2 is a schematic plane view of a diaphragm and a frame according to the first embodiment.

FIG. 3 is a schematic vertical sectional view of a wafer according to the first embodiment.

FIG. 4 is a flowchart showing the flow of a process executed in the electrolytic plating apparatus according to the first embodiment.

FIG. 5 is a flowchart showing the flow of a plating process according to the first embodiment.

FIG. 6A and FIG. 6B are views schematically showing the state in the electrolytic plating apparatus according to the first embodiment.

FIG. 7 is a schematic plane view of a dummy wafer according to a second embodiment.

FIG. 8 is a view showing the state in a holder vessel when the dummy wafer according to the second embodiment is housed in the holder vessel.

FIG. 9 is a flowchart showing the flow of a process executed in an electrolytic plating apparatus according to the second embodiment.

FIG. 10 is a flowchart showing the flow of a plating process in the dummy wafer executed in the electrolytic plating apparatus according to the second embodiment.

FIG. 11A to FIG. 11C are views schematically showing the state in the electrolytic plating apparatus according to the second embodiment.

FIG. 12 is a flowchart showing the flow of a process executed in an electrolytic plating apparatus according to a third embodiment.

FIG. 13 is a flowchart showing the flow of a plating process in a dummy wafer executed in the electrolytic plating apparatus according to the third embodiment.

FIG. 14 is a view schematically showing the state in the electrolytic plating apparatus according to the third embodiment.

### BEST MODE FOR CARRYING OUT THE INVENTION

### First Embodiment

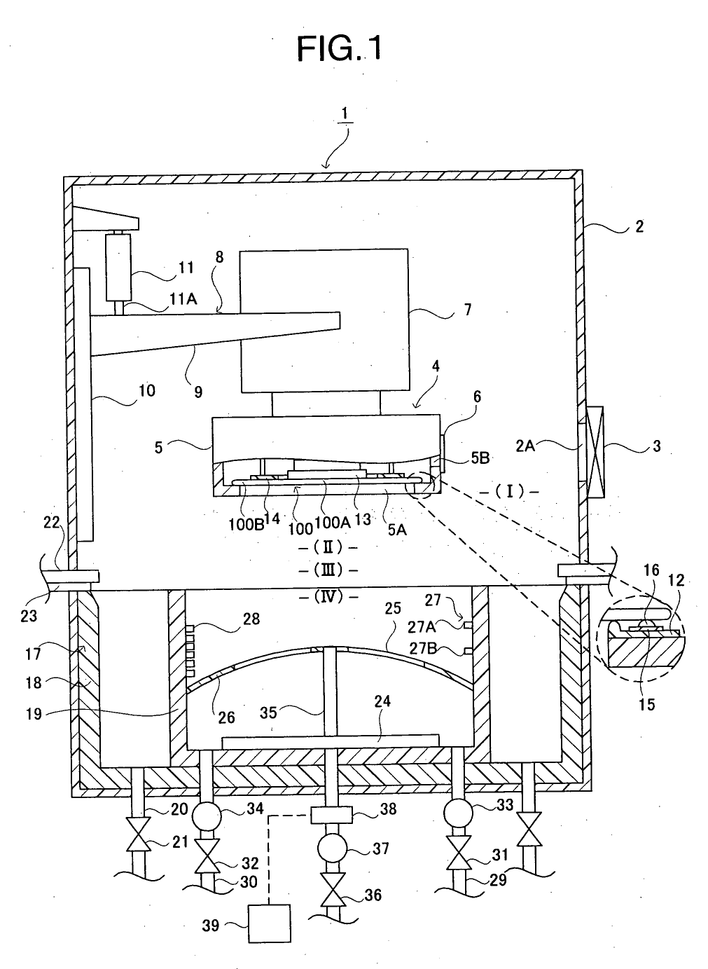

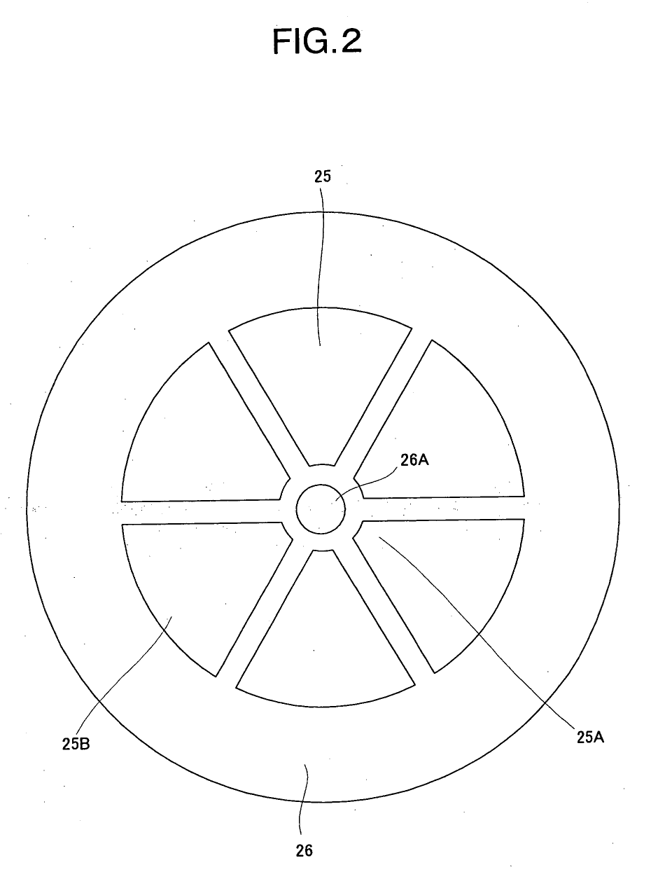

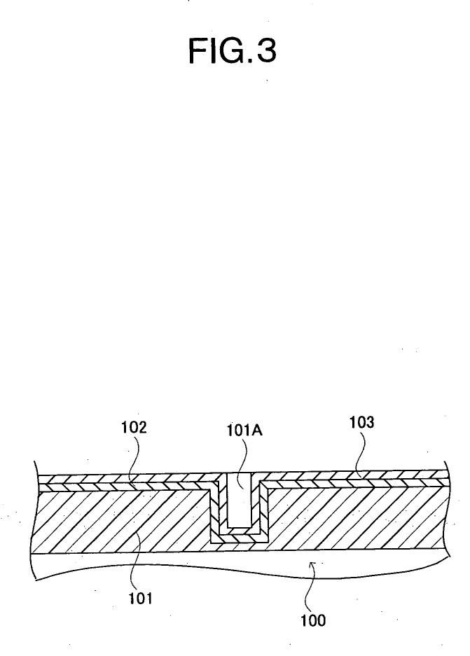

An electrolytic plating apparatus according to a first embodiment will be hereinafter explained. FIG. 1 is a schematic vertical sectional view of the electrolytic plating apparatus according to, this embodiment, and FIG. 2 is a schematic plane view of a diaphragm and a frame according to this embodiment. FIG. 3 is a schematic vertical sectional view of a wafer according to this embodiment.

As shown in FIG. 1 and FIG. 2, an electrolytic plating apparatus 1 has a housing 2 made of synthetic resin or the like. An opening 2A is formed on a sidewall of the housing 2. A gate valve 3 that opens/closes when a wafer 100 is carried into and out of the electrolytic plating apparatus 1 is disposed on an outer side of the opening 2A.

A holder 4 to hold the wafer 100 is disposed in the housing 2. The wafer 100 is held by the holder 4 in a so-called facedown manner so that a surface to be plated of the wafer 100 faces downward.

The holder 4 has a holder vessel 5 in a substantially cylindrical shape for housing the wafer 100 in its inner space substantially horizontally. An opening 5A in a substantially circular shape for allowing the surface to be plated of the wafer 100 to be in contact with a plating solution is formed on a bottom face of the holder vessel 5. The opening 5A is formed to have a diameter smaller than that of the wafer 100.

An opening 5B through which the wafer 100 is to be carried into or out of the holder vessel 5 is formed on a side face of the holder vessel 5. A shutter 6 that can be freely opened/closed is disposed on an outer side of the opening 5B. After the wafer 100 is carried in, the shutter 6 is closed to cover the opening 5B, so that the entrance of the plating solution into the holder vessel 5 is prevented.

A motor 7 to rotate the holder vessel 5 in a substantially horizontal plane is connected to the holder vessel 5. Note that the wafer 100 rotates with the holder vessel 5 when the holder vessel 5 rotates.

A holder vessel hoisting/lowering mechanism 8 to hoist/lower the holder vessel 5 is attached to the motor 7. The holder vessel hoisting/lowering mechanism 8 is composed of a support beam 9 attached to the motor 7, a guide rail 10 attached to an inner wall of the housing 2, and an air cylinder 11 having an extendible/contractible rod 11A and hoisting/lowering the support beam 9 along the guide rail 10. The actuation of the air cylinder 11 causes the rod 11A to extend/contract, so that the holder vessel 5 is hoisted/lowered along the guide rail 10.

Specifically, the holder vessel 5 is hoisted/lowered by the holder vessel hoisting/lowering mechanism 8 among a transfer position (I) where the wafer 100 is transferred, a cleaning position (II) where plating applied on the wafer 100 is cleaned, a spin-dry position (III) where the plated wafer 100 is spin-dried for the removal of an unnecessary plating solution or water therefrom, and a plating position (IV) where the wafer 100 is plated. Incidentally, when the plating solution is filled in an inner tank 19 which will be described later, the transfer position (I), the cleaning position (II), and the spin-dry position (III) are positioned higher than the level of the plating solution, and the plating position (IV) is positioned lower than the level of the plating solution.

A seal member 12 that prevents later-described cathode electrodes 15 from coming into contact with the plating solution is disposed in the holder vessel 5. A suction pad 13 for holding the wafer. 100 and placing the wafer. 100 on the seal member 12, and a pressing member 14 for pressing the wafer 100 placed on the seal member 12 against the seal member 12 are further disposed in the holder vessel 5.

The plural cathode electrodes 15 to be in electrical contact with the wafer 100 are disposed on the seal member 12. The plural cathode electrodes 15 are provided, so that electricity is supplied from a plurality of places, resulting in uniform current passage through the wafer 100. The cathode electrodes 15 are formed of a material excellent in electrical conductivity, for example, Au, Pt, or the like.

Hemispheric contacts 16 which are brought into contact with an outer periphery portion of the surface to be plated of the wafer 100 at, for example, 128 equally divided positions are protrudingly provided on the cathode electrodes 15. By the hemispheric formation of the contacts 16, each of the contacts 16 is in contact with the wafer 100 with a constant area.

The wafer 100 to be in contact with the contacts 16 includes an interlayer insulation film 101 in which wiring trenches 101A are formed, as shown in FIG. 3. The interlayer insulation film 101 is preferably formed of a low dielectric constant material, for example, SiOF, SiOC, porous silica, or the like. Further, connection holes may be formed in the interlayer insulation film 101 in place of or in addition to the wiring trenches 101A.

A barrier film 102 to inhibit the diffusion of the plating to the interlayer insulation film 101 is formed on the interlayer insulation film 101. The barrier film 102 is preferably formed of, for example, TaN, TiN, or the like. Further, the barrier film 102 is formed on the interlayer insulation film 101 to have a thickness of about 30 nm.

A seed film 103 for allowing a current to pass through the wafer 100 is formed on the barrier film 101. The seed film 103 is preferably formed of the same metal as the plating. Specifically, if the plating is, for example, Au, Ag, Pt, Cu, or the like, the seed film 103 is preferably formed of, for example, Au, Ag, Pt, Cu, or the like in conformity to the plating. Further, the seed film 103 is formed on the barrier film 102 to have a thickness of about 100 nm.

A plating solution tank 17 for storing the plating solution therein is disposed beneath the holder 4. The plating solution tank 17 is constituted of an outer tank 18 and an inner tank 19 disposed inside the outer tank 18. The outer tank 18 is intended for receiving the plating solution overflowing from the inner tank 19. The outer tank 18 is formed in a substantially cylindrical shape with its top face opened and bottom face closed. A drainpipe 20 through which the plating solution is drained from the outer tank 18 is connected to a bottom portion of the outer tank 118. The other end of the drainpipe 20 is connected to a not-shown reservoir tank in which the plating solution to be supplied to the inner tank 19 is stored. A valve 21 is disposed in the middle of the drainpipe 20. When the valve 21 is opened, the plating solution overflowing from the inner tank 19 and flowing into the outer tank 18 is returned to the reservoir tank.

On an upper portion of the outer tank 18, an exhaust member 22 having an exhaust port to suck the vaporized plating solution or the scattered plating solution and a washing nozzle 23 to clean the plating applied on the wafer 100 are disposed.

The inner tank 19 is intended for storing the plating solution in which the wafer 100 is to be immersed. Similarly to the outer tank 18, the inner tank 19 is formed in a substantially cylindrical shape with its top face opened and bottom face closed. An anode electrode 24 is disposed on the bottom portion of the inner tank 19, a voltage being applied between the cathode electrodes 15 and the anode electrode 24. The anode electrode 24 is electrically connected to a not-shown external power source.

A diaphragm 25 that partitions the inside of the inner tank 19 to an upper region and a lower region is disposed above the anode electrode 24. Here, the lower region and the upper region separated by the diaphragm 25 are called an anode region and a cathode region respectively. The diaphragm 25 is an ion conductive film. Specifically, the diaphragm 25 is mainly made of titanium oxide, polyvinylidene fluoride, and so on.

The diaphragm 25 is constituted of a plurality, six pieces in this embodiment, of diaphragm pieces arranged in a ring form. The diaphragm 25 is supported by a frame 26 formed of a transformable material, for example, polyethylene.

A periphery portion of the frame 26 is fixed to the inner tank 19. An opening 26A is formed on a center portion of the frame 26, and a tip portion of a later-described supply pipe 35 is liquid-tightly connected to the opening 26A. The center portion of the frame 26 is positioned closer to a wafer 100 side than the periphery portion of the frame 26. Specifically, the frame 26 is formed in a dome shape in this embodiment. The frame 26 is formed in such a shape, so that a portion 25A (hereinafter, referred to as a center facing portion 25A) of the diaphragm 25 facing a center portion 100A of the wafer 100 is positioned closer to the wafer 100 side than a portion 25B (hereinafter, referred to as a periphery facing portion 25B) of the diaphragm 25 facing a periphery portion 100B of the wafer 100.

A light-emitting element 27 to emit light at a predetermined angle to the wafer 100 and light-receiving elements 28 to detect the light reflected on the wafer 100 are provided in the inner tank 19. The light-emitting element 27 is constituted of a light-emitting element 27A to emit light at a predetermined angle to the center portion 100A of the wafer 100 and a light-emitting element 27B to emit light at a predetermined angle to the periphery portion 100B of the wafer 100. The plural light-receiving elements 28 are arranged in line. The light-emitting element 27 and the light-receiving elements 28 are disposed, so that the film thickness of the plating can be measured. To be more specific, as the plating of the wafer 100 progresses, the reflection position of the light emitted from the light-emitting element 27 shifts toward the light-emitting element 27 side. When the reflection position shifts toward the light-emitting element 27 side, the reflected light moves downward to cause the change in the light-receiving position. This change in the light-receiving position is detected by the light-receiving elements 28, so that a later-described controller 39 can calculate the film thickness of the plating.

A supply pipe 29 through which the plating solution is supplied to the anode region and a drainpipe 30 through which the plating solution is drained from the anode region are connected to the bottom portion of the inner tank 19. Valves 31, 32 that can be opened/closed freely and pumps 33, 34 capable of adjusting a flow rate of the plating solution are provided in the middle of the supply pipe 29 and the drain pipe 30 respectively. When the pump 33 is put into operation while the valve 31 is open, the plating solution in the reservoir tank is sent to the anode region at a predetermined flow rate. Further, when the pump 34 is put into operation while the valve 32 is open, the plating solution in the anode region is returned to the reservoir tank.

The supply pipe 35 through which the plating solution is supplied to the cathode region protrudes into the inner tank 19. The other end of the supply pipe 35 is connected to the not-shown reservoir tank. A valve 36 that can be opened and closed freely and a pump 37 capable of adjusting the flow rate of the plating solution are provided in the middle of the supply pipe 35. When the pump 37 is put into operation while the valve 36 is open, the plating solution in the reservoir tank is sent to the cathode region at a predetermined flow rate.

A supply pipe extending/contracting mechanism 38 that extends/contracts the supply pipe 35 in a thickness direction of the wafer 100 is attached to the supply pipe 35. Here, the frame 26 supporting the diaphragm 25 is connected to the tip of the supply pipe 35, so that the extension/contraction of the supply pipe 35 by the operation of the supply pipe extending/contracting mechanism 38 causes the center portion of the frame 26 and the center facing portion 25A of the diaphragm 25 to vertically move.

The controller 39 that controls the operation of the supply pipe extending/contracting mechanism 38 is electrically connected to the supply pipe extending/contracting mechanism 38. The controller 39 is electrically connected to the light-receiving elements 28 as well. The controller 39 controls the operation of the supply pipe extending/contracting mechanism 38 based on output signals from the light-receiving elements 28. Specifically, the controller 39 calculates the film thickness of the center portion 100A of the wafer 100 and the film thickness of the periphery portion 100B thereof based on the output signals from the light-receiving elements 28 to judge whether or not the film thickness of the center potion 10A is larger than the film thickness of the periphery portion 100B. When judging that the film thickness of the center portion 100A is larger than the film thickness of the periphery portion 100B, it outputs to the supply pipe extending/contracting mechanism 38 a control signal causing the supply pipe 35 to contract. When judging that the film thickness of the center portion 100A is smaller than the film thickness of the periphery portion 100B, it outputs to the supply pipe extending/contracting mechanism 38 a control signal causing the supply pipe 35 to extend.

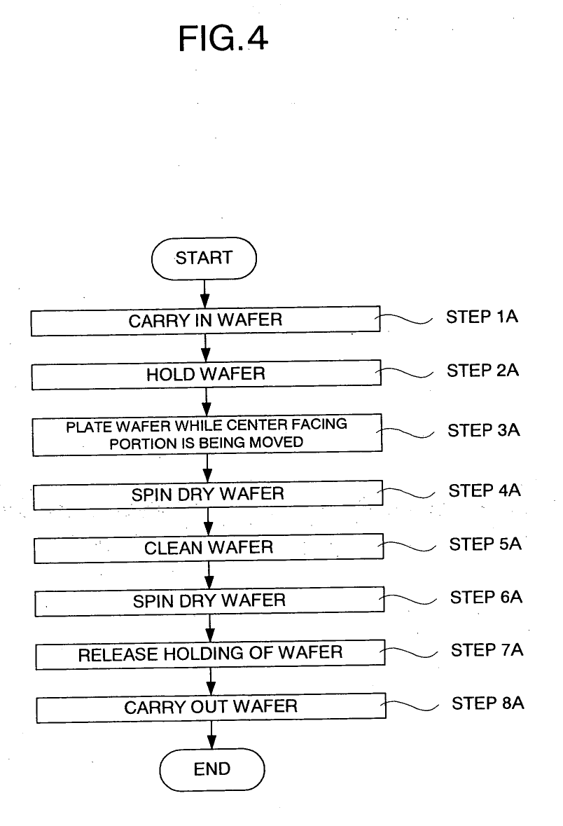

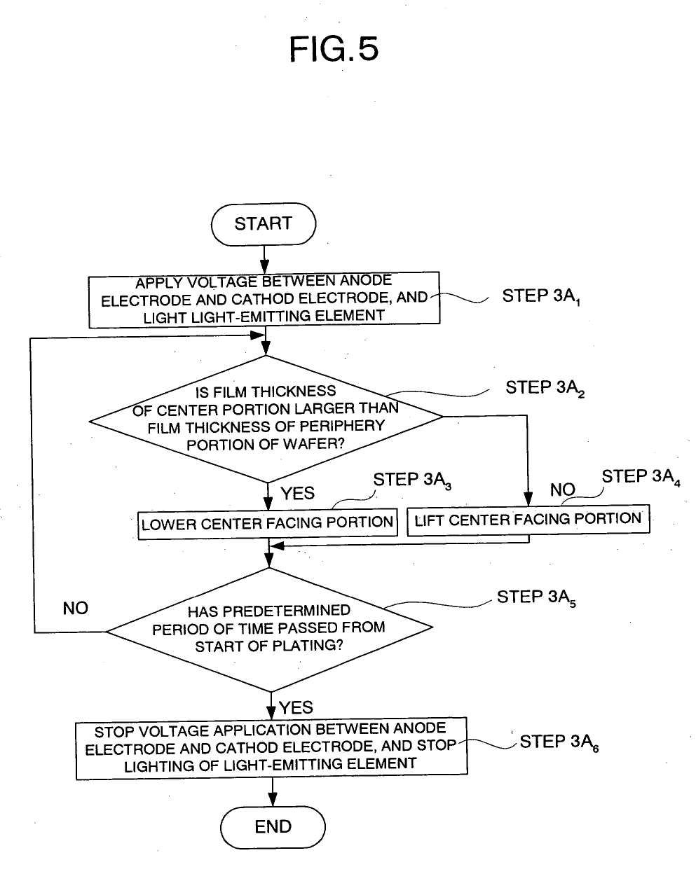

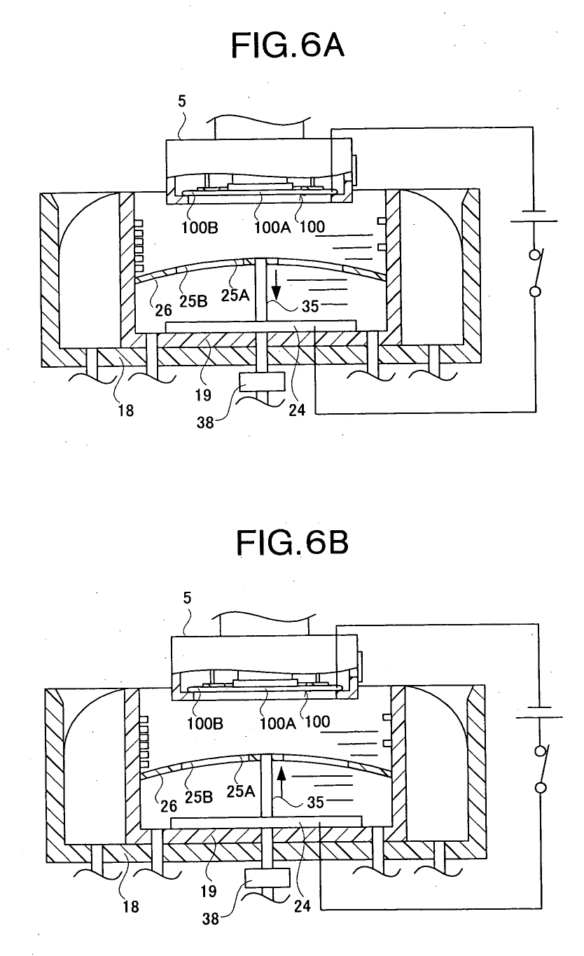

Hereinafter, the flow of a process executed in an electrolytic plating apparatus 1 will be explained with reference to FIG. 4 to FIG. 6B. FIG. 4 is a flowchart showing the flow of a process executed in the electrolytic plating apparatus 1 according to this embodiment, FIG. 5 is a flowchart showing the flow of a plating process according to this embodiment, and FIG. 6A and FIG. 6B are views schematically showing the state inside the electrolytic plating apparatus 1 according to this embodiment.

First, while the gate valve 3 is open, a not-shown carrier arm holding the wafer 100 extends into the holder vessel 5 positioned at the transfer position (I) to carry the wafer 100 into the electrolytic plating apparatus 1 (Step IA).

After the wafer 100 is carried into the electrolytic plating apparatus 1, the wafer 100 is suction-held by the suction pad 13. Subsequently, the suction pad 13 moves down to place the wafer 100 on the seal member 12. Thereafter, the pressing member 14 moves down to press the wafer 100 against the seal member 12. With this process, the wafer 100 is held by the holder 4 (Step 2A).

After the wafer 100 is held by the holder 4, the air cylinder 11 is actuated to lower the holder vessel 5 to the plating position (IV), so that the wafer 100 is immersed in the plating solution. After the holder vessel 5 is positioned at the plating position (IV), the wafer 100 is plated while the operation of the supply pipe extending/contracting mechanism 38 is being controlled (Step 3A).

Specifically, a voltage is first applied between the anode electrode 24 and the cathode electrodes 15. Further, the light-emitting element 27 is lighted, so that the light is emitted from the light-emitting element 27. (Step 3A₁). Thereafter, the controller 39 calculates the film thickness of the center portion 100A of the wafer 100 and the film thickness of the periphery portion 100B thereof based on the output signals from the light-receiving elements 28 to judge whether or not the film thickness of the center portion 100A is larger than the film thickness of the periphery portion 100B (Step 3A₂). When it is judged that the film thickness of the center portion 100A is larger than the film thickness of the periphery portion 100B, the supply pipe 35 contracts as shown in FIG. 6A to lower the center facing portion 25A (Step 3A₃). On the other hand, when it is judged that the film thickness of the center portion 100A is smaller than the film thickness of the periphery portion 100B, the supply pipe 35 extends as shown in FIG. 6B to lift the center facing portion 25A (Step 3A₄). Thereafter, it is judged whether or not a predetermined period of time has passed from the start of the plating (Step 3A₅). When it is judged that the predetermined period of time has not passed from the start of the plating, the processes from Step 3A₂ to Step 3A₄ are repeated. When it is judged that the predetermined period of time has passed from the start of the plating, the voltage application is stopped and the lighting of the light-emitting element 27 is stopped (Step 3A₆). With this process, the plating of the wafer 100 is finished.

After the plating of the wafer 100 is finished, the air cylinder 11 is actuated to lift the holder vessel 5 to the spin-dry position (III). After the holder vessel 5 is positioned at the spin-dry position (III), the holder vessel 5 is rotated in a substantially horizontal plane by the drive of the motor 7 for spin dry (Step 4A).

After the spin dry is finished, the air cylinder 11 is actuated to lift the holder vessel 5 to the cleaning position (II). After the holder vessel 5 is positioned at the cleaning position (II), the holder vessel 5 is rotated in a substantially horizontal plane by the drive of the motor 7 and pure water is sprayed to the wafer 100 from the washing nozzle 23 to clean the plating applied on the wafer 100 (Step 5A).

After the cleaning of the plating is finished, the air cylinder 11 is actuated to lower the holder vessel 5 to the spin-dry position (III). After the holder vessel 5 is positioned at the spin-dry position (III), the holder vessel 5 is rotated in a substantially horizontal plane by the drive of the motor 7 spin dry (Step 6A).

After the spin dry is finished, the air cylinder 11 is actuated to lift the holder vessel 5 to the transfer position (I). After the holder vessel 5 is positioned at the transfer position (I), the pressing member 14 moves up to release the pressing to the wafer 100. Thereafter, the suction pad 13 moves up to have the wafer 100 apart from the seal member 12. With this process, the holding of the wafer 100 by the holder 4 is released (Step 7A).

After the holding of the wafer 100 is released, the shutter 6 and the gate valve 3 are opened, and the not-shown carrier arm extends into the holder vessel 5 to receive the wafer 100. Thereafter, the carrier arm holding the wafer 100 contracts to carry the wafer 100 out of the electrolytic plating apparatus 1 (Step 8A).

In this embodiment, the center facing portion 25A is moved relative to the periphery portion 25B during the plating process based on the film thicknesses of the plating applied on the center portion 10A and the periphery portion 10B, which enables effective improvement in plating uniformity in a surface. Specifically, the diaphragm 25 gives an influence to the current density due to its ion conductivity. To be more specific, as the distance from the wafer 100 to the diaphragm 25 decreases, the current density in the wafer 100 increases, and as the distance from the wafer 100 to the diaphragm 25 increases, the current density decreases. Therefore, when the center facing portion 25A moves down to increase the distance between the center portion 100A and the center facing portion 25A, the current density of the center portion 100A decreases, and when the center facing portion 25A moves up to decrease the distance between the center portion 100A and the center facing portion 25A, the current density of the center portion 100A increases. Here, in this embodiment, the center facing portion 25A moves up or down based on the film thicknesses of the plating applied on the center portion 100A and the periphery portion 100B. Since a shielding plate is not provided, the plating solution in the cathode region flows smoothly. As a result, higher uniformity of the flow velocity distribution can be realized than that when the shielding plate is provided. Therefore, plating uniformity in a surface can be effectively improved.

In this embodiment, since the center facing portion 25A is moved, partial change in the distance between the wafer 100 and the diaphragm 25 can be more easily made than when the periphery facing portion 25B is moved.

### Second Embodiment

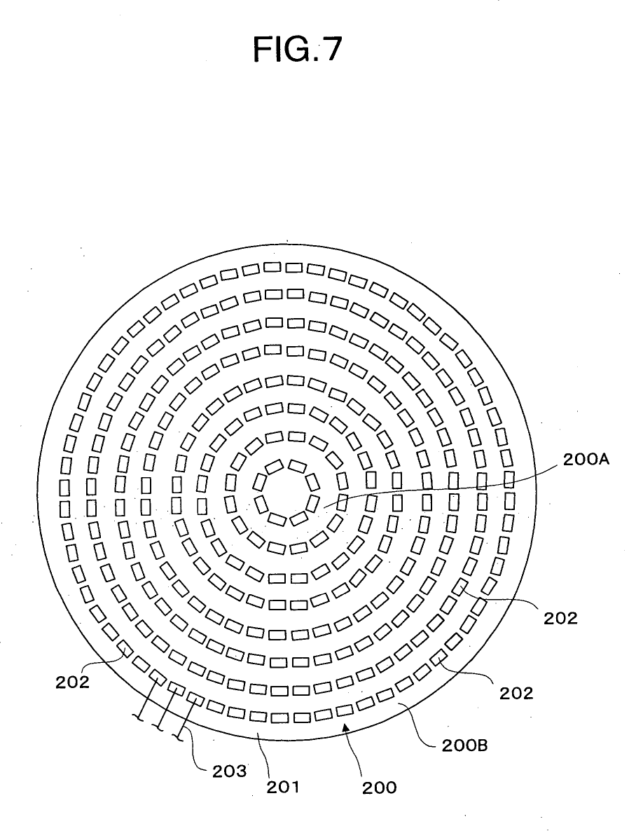

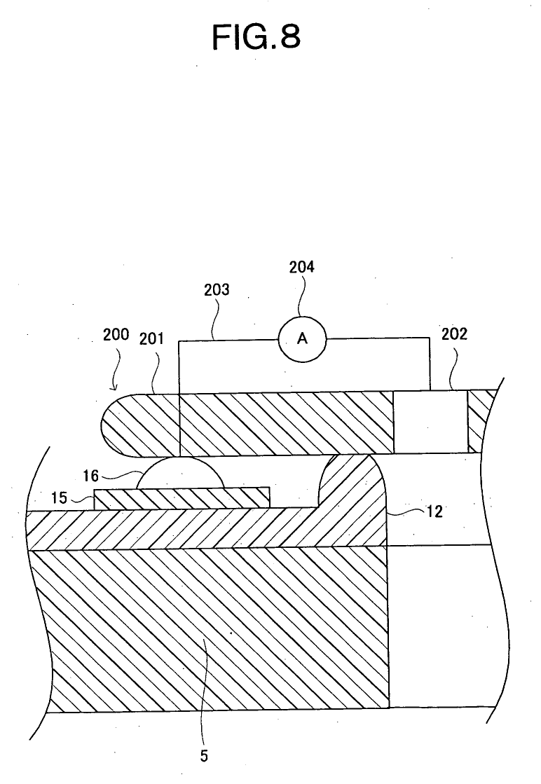

Hereinafter, a second embodiment will be explained. Note that in this embodiment and a subsequent embodiment, the same contents as those in the previous embodiment(s) will be omitted in some cases. The explanation in this embodiment will be given on an example where, through the use of a dummy wafer, a current passing through a center portion and a current passing through a periphery portion are measured and a wafer is plated based on the currents. FIG. 7 is a schematic plane view of a dummy wafer according to this embodiment, and FIG. 8 is a view showing the state in a holder vessel when the dummy wafer according to this embodiment is housed in the holder vessel.

As shown in FIG. 7 and FIG. 8, a dummy wafer 200 has a monitor electrode support plate 201 formed of, for example, synthetic resin or the like, and supporting later-described monitor electrodes 202. A plurality of openings are formed in the monitor electrode support plate 201, and the monitor electrodes 202 formed of, for example, Cu, Pt, or the like are buried in these openings.

The monitor electrodes 202 are buried in such a manner, for example, that the entire monitor electrodes 202 form a plurality of rings concentric with the monitor electrode support plate 201. Note that, for example, 64 or 128 pieces of the monitor electrodes 202 are buried in a periphery portion of the monitor electrode support plate 201.

Lead wires 203 for electrical contact between the monitor electrodes 202 and contacts 16 are connected to the monitor electrodes 202. When the dummy wafer 200 is placed on the contacts 16, the lead wires 203 come into contact with the contacts 16 to bring the monitor electrodes 202 and the contacts 16 in electrical contact with each other. Ammeters 204 to measure currents passing through the monitor electrodes 202 are provided in the middle of the lead wires 203, and a controller 39 is electrically connected to the ammeters 204.

The controller 39 controls the operation of a supply pipe extending/contracting mechanism 38 based on output signals from the ammeters 204. Specifically, the controller 39 judges, based on the output signal from the ammeters 204, whether or not a current passing through a center portion 200A of the dummy wafer 200 is larger than a current passing through a periphery portion 200B thereof. When judging that the current passing through the center portion 200A is larger than the current passing through the periphery portion 200B, it outputs to the supply pipe extending/contracting mechanism 38 a control signal causing a supply pipe 35 to contract. On the other hand, when judging that the current passing through the center portion 200A is smaller than the current passing through the periphery portion 200B, it outputs to the supply pipe extending/contracting mechanism 38 a control signal causing the supply pipe 35 to extend. Here, the control signal outputted when the dummy wafer 200 is plated is stored in the controller 39, and the stored control signal is outputted when a wafer 100 is plated. Consequently, the control over the supply pipe extending/contracting mechanism 38 that is performed when the dummy wafer 200 is plated is reproduced when the wafer 100 is plated.

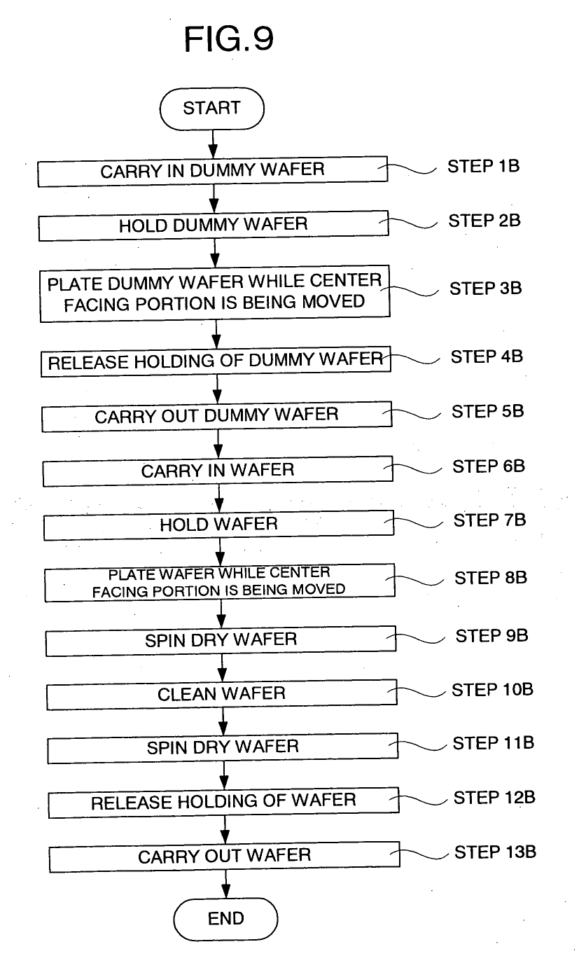

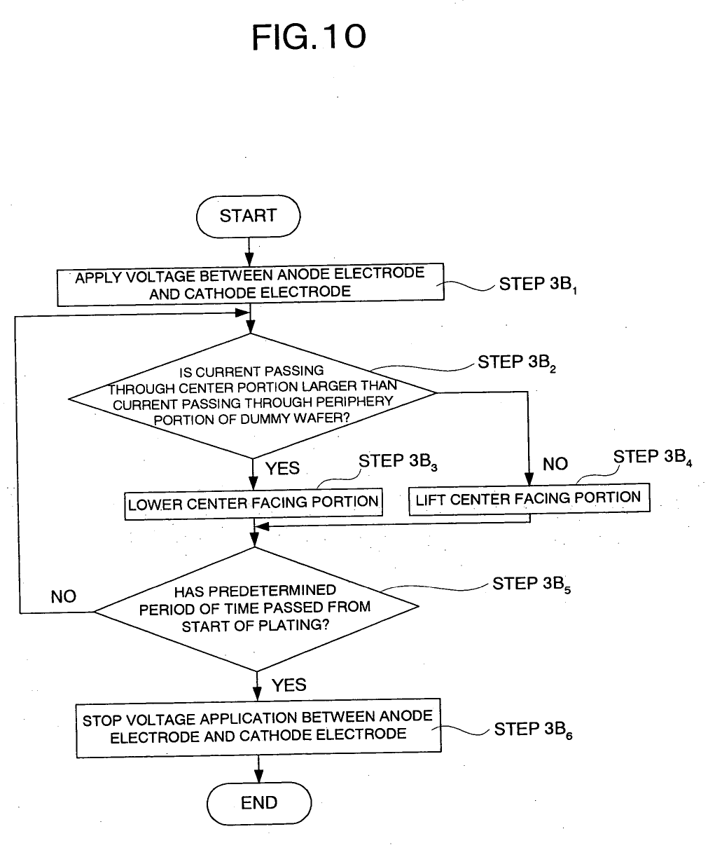

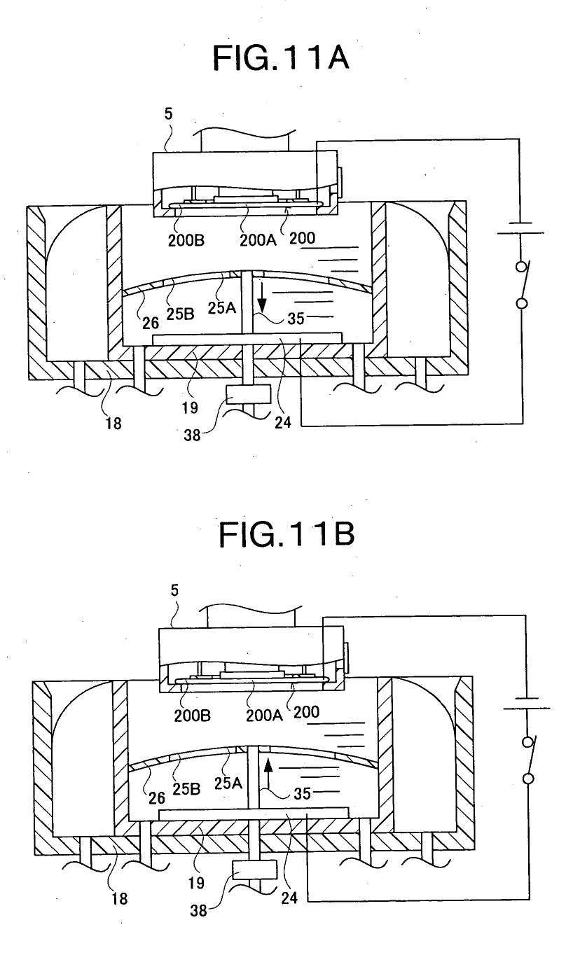

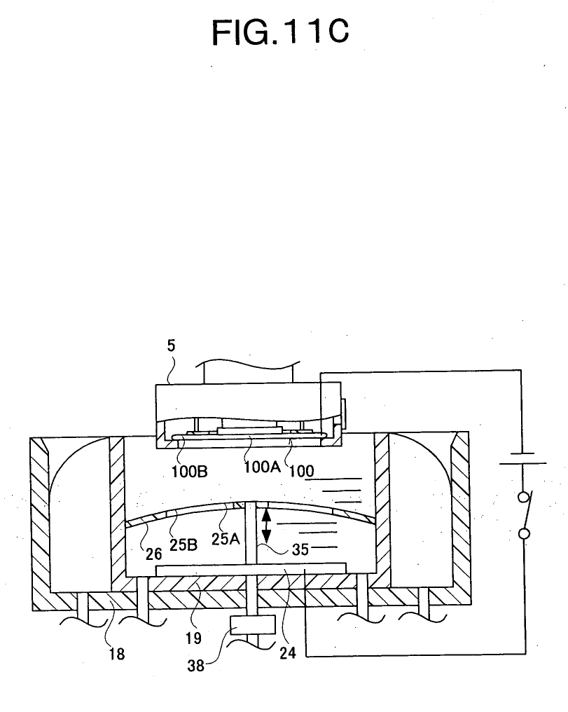

Hereinafter, the flow of a process executed in an electrolytic plating apparatus 1 will be explained with reference to FIG. 9 to FIG. 11. FIG. 9 is a flowchart showing the flow of a process executed in the electrolytic plating apparatus 1 according to this embodiment, FIG. 10 is a flowchart showing the flow of the plating process in the dummy wafer 200 executed in the electrolytic plating apparatus 1 according to this embodiment, and FIG. 11A to FIG. 11C are views schematically showing the state in the electrolytic plating apparatus 1 according to this embodiment.

First, while a gate valve 3 is open, a not-shown carrier arm holding the dummy wafer 200 extends into a holder vessel 5 to carry the dummy wafer 200 into the electrolytic plating apparatus 1 (Step 1B).

After the dummy wafer 200 is carried into the electrolytic plating apparatus 1, the dummy wafer 200 is suction-held by a suction pad 13. Subsequently, the suction pad 13 moves down to place the dummy wafer 200 on a seal member 12. Thereafter, a pressing member 14 moves down to press the dummy wafer 200 against the seal member 12. With this process, the dummy wafer 200 is held by a holder 4 (Step 2B).

After the dummy wafer 200 is held by the holder 4, the holder vessel 5 moves down to a plating position (IV), so that the dummy wafer 200 is immersed in a plating solution. After the holder vessel 5 is positioned at the plating position (IV), the dummy wafer 200 is plated while the operation of the supply pipe extending/contracting mechanism 38 is being controlled (Step 3B).

Specifically, a voltage is first applied between an anode electrode 24 and cathode electrodes 15 (Step 3B₁). Thereafter, the controller 39 judges whether or not the current passing through the center portion 200A of the dummy wafer 200 is larger than the current passing through the periphery portion 200B thereof based on the output signals from the ammeters 204 (Step 3B₂). When it is judged that the current passing through the center portion 200A is larger than the current passing through the periphery portion 200B, the supply pipe 35 contracts as shown in FIG. 1A to lower a center facing portion 25A (Step 3B₃). On the other hand, when it is judged that the current passing through the center portion 200A is smaller than the current passing through the periphery portion 200B, the supply pipe 35 extends as shown in FIG. 11B to lift the center facing portion 25A (Step 3B₄). Thereafter, it is judged whether or not a predetermined period of time has passed from the start of the plating (Step 3B₅). When it is judged that the predetermined period of time has not passed from the start of the plating, the processes from Step 3B₂ to Step 3B₅ are repeated. When it is judged that the predetermined period of time has passed from the start of the plating, the voltage application is stopped (Step 3B₆). With this process, the plating of the dummy wafer 200 is finished.

After the plating of the dummy wafer 200 is finished, the holder vessel 5 moves up to a transfer position (I). After the holder vessel 5 is positioned at the transfer position (I), the pressing member 14 moves up to release the pressing to the dummy wafer 200. Thereafter, the suction pad 13 moves up to have the dummy wafer 200 apart from the seal member 12. With this process, the holding of the dummy wafer 200 by the holder 4 is released (Step 4B)

After the holding of the dummy wafer 200 is released, the carrier arm receives the dummy wafer 200. Thereafter, the carrier arm holding the dummy wafer 200 contracts to carry the dummy wafer 200 out of the housing 2 (Step 5B).

After the dummy wafer 200 is carried out of the electrolytic plating apparatus 1, a not-shown carrier arm holding the wafer 100 extends into the holder vessel 5 to carry the wafer 100 into the electrolytic plating apparatus 1 (Step 6B).

After the wafer 100 is carried into the electrolytic plating apparatus 1, the wafer 100 is suction-held by the suction pad 13. Subsequently, the suction pad 13 moves down to place the wafer 100 on the seal member 12. Thereafter, the pressing member 14 moves down to press the wafer 100 against the seal member 12. With this process, the wafer 100 is held by the holder 4 (Step 7B).

After the wafer 100 is held by the holder 4, the holder vessel 5 moves down to the plating position (IV), so that the wafer 100 is immersed in the plating solution. After the holder vessel 5 is positioned at the plating position (IV), a voltage is applied between the anode electrode 24 and the cathode electrodes 15, and the wafer 100 is plated while the movement of the center facing portion 25A that was made when the dummy wafer 200 was plated is reproduced, as shown in FIG. 11C (Step 8B).

After the plating of the wafer 100 is finished, the holder vessel 5 moves up to a spin-dry position (III). After the holder vessel 5 is positioned at the spin-dry position (III), the holder vessel 5 is rotated in a substantially horizontal plane for spin dry (Step 9B).

After the spin dry is finished, the holder vessel 5 moves up to a cleaning position (II). After the holder vessel 5 is positioned at the cleaning position (II), the holder vessel 5 is rotated in a substantially horizontal plane and pure water is sprayed to the wafer 100 from a washing nozzle 23 to clean the plating applied on the wafer 100 (Step 10B).

After the plating is cleaned, the holder vessel 5 moves down to the spin-dry position (III). After the holder vessel 5 is positioned at the spin-dry position (III), the holder vessel 5 is rotated in a substantially horizontal plane for spin dry (Step 1B).

After the spin dry is finished, the holder vessel 5 moves up to the transfer position (I). After the holder vessel 5 is positioned at the transfer position (I), the pressing member 14 moves up to release the pressing to the wafer 100. Thereafter, the suction pad 13 moves up to have the wafer 100 apart from the seal member 12. With this process, the holding of the wafer 100 by the holder 4 is released (Step 12B).

After the holding of the wafer 100 is released, the carrier arm receives the wafer 100. Thereafter, the carrier arm holding the wafer 100 contracts to carry the wafer 100 out of the electrolytic plating apparatus 1 (Step 13B).

### Third Embodiment

Hereinafter, a third embodiment will be explained. The explanation in this embodiment will be given on an example where the positioning of a center facing portion is made through the use of a dummy wafer, and thereafter a wafer is plated with the center facing portion being fixed.

A controller 39 controls the operation of a supply pipe extending/contracting mechanism 38 based on output signals from ammeters 204. Specifically, it is judged, based on the output signals from the ammeters 204, whether or not the difference between a current passing through a center portion 200A of a dummy wafer 200 and a current passing through a periphery portion 200B thereof is within a predetermined range. When the difference between the current passing through the center portion 200A and the current passing through the periphery portion 200B is not within the predetermined range, it is judged whether or not the current passing through the center portion 200A is larger than the current passing through the periphery portion 200B. When the current passing through the center portion 200A is larger than the current passing through the periphery portion 200B, a control signal causing a supply pipe 35 to contract is outputted to the supply pipe extending/contracting mechanism 38. On the other hand, when it is judged that the current passing through the center portion 200A is smaller than the current passing through the periphery portion 200B, a control signal causing the supply pipe 35 to extend is outputted to the supply pipe extending/contracting mechanism 38. On the other hand, when the difference between the current passing through the center portion 200A and the current passing through the periphery portion 200B is within the predetermined range, a control signal causing the supply pipe 35 to stop is outputted to the supply pipe extending/contracting mechanism 38.

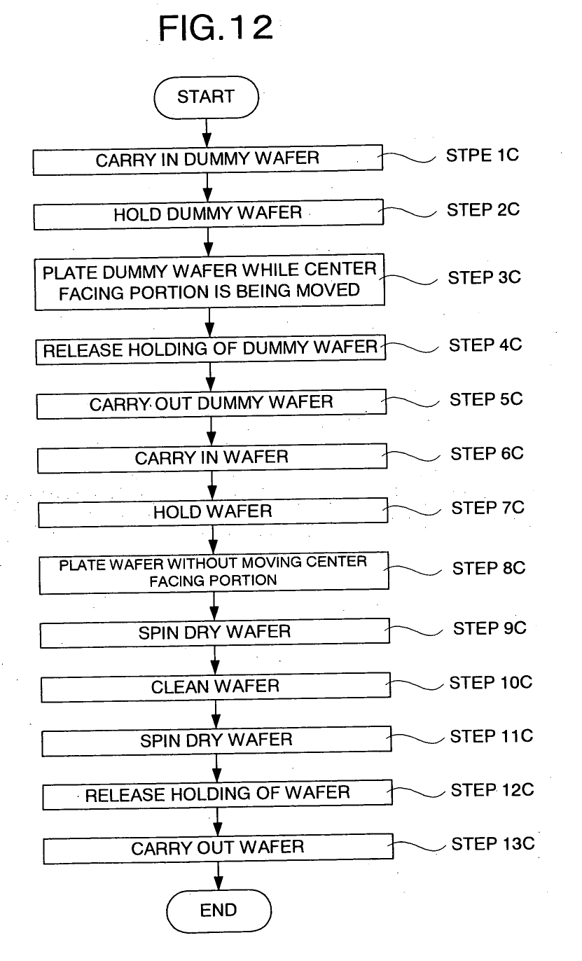

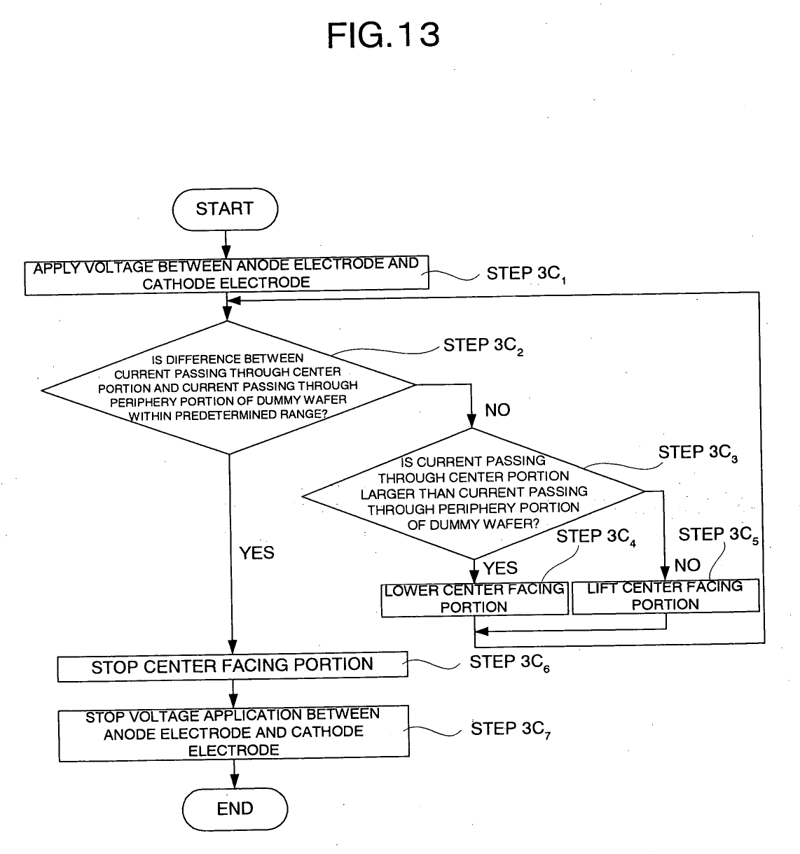

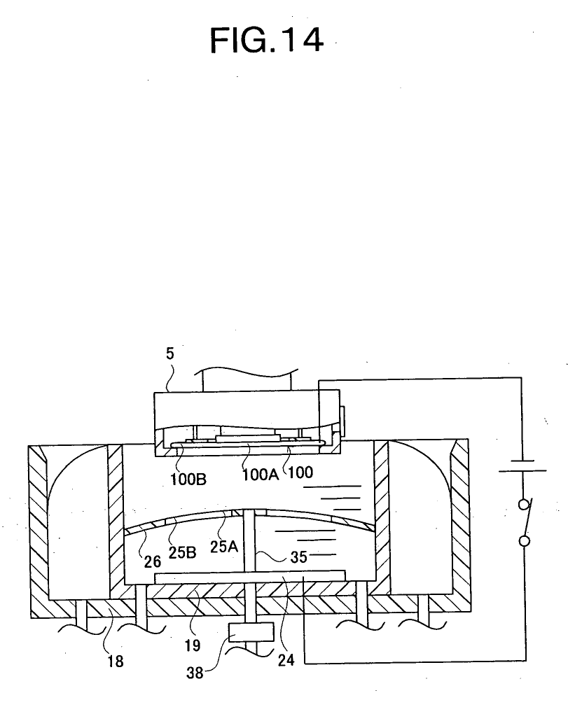

Hereinafter, the flow of a process executed in an electrolytic plating apparatus 1 will be explained with reference to FIG. 12 to FIG. 14. FIG. 12 is a flowchart showing the flow of a process executed in the electrolytic plating apparatus 1 according to this embodiment, FIG. 13 is a flowchart showing the flow of a plating process in the dummy wafer 200 executed in the electrolytic plating apparatus 1 according to this embodiment, and FIG. 14 is a view schematically showing the state in the electrolytic plating apparatus 1 according to this embodiment.

First, while a gate valve 3 is open, a not-shown carrier arm holding the dummy wafer 200 extends into a holder vessel 5 to carry the dummy wafer 200 into the electrolytic plating apparatus 1 (step 1C).

After the dummy wafer 200 is carried into the electrolytic plating apparatus 1, the dummy wafer 200 is suction-held by a suction pad 13. Subsequently, the suction pad 13 moves down to place the dummy wafer 200 on a seal member 12. Thereafter, a pressing member 14 moves down to press the dummy wafer 200 against the seal member 12. With this process, the dummy wafer 200 is held by a holder 4 (Step 2C).

After the dummy wafer 200 is held by the holder 4, the holder vessel 5 moves down to a plating position (IV), so that the dummy wafer 200 is immersed in a plating solution. After the holder vessel 5 is positioned at the plating position (IV), the dummy wafer 200 is plated while the operation of the supply pipe extending/contracting mechanism 38 is being controlled (Step 3C).

Specifically, a voltage is first applied between an anode electrode 24 and cathode electrodes 15 (Step 3C₁). Thereafter, the controller 39 judges, based on the output signals from the ammeters 204, whether or not the difference between the current passing through the center portion 200A of the dummy wafer 200 and the current passing through the periphery portion 200B thereof is within the predetermined range (Step 3C₂); When the difference between the current passing through the center portion 200A and the current passing through the periphery portion 200B is not within the predetermined range, it is judged whether or not the current passing through the center portion 200A is larger than the current passing through the periphery portion 200B (Step 3C₃). When it is judged that the current passing through the center portion 200A is larger than the current passing through the periphery portion 200B, the supply pipe 35 contracts to lower a center facing portion 25A (Step 3C₄). On the other hand, when it is judged that the current passing through the center portion 200A is smaller than the current passing through the periphery portion 200B, the supply pipe 35 extends to lift the center facing portion 25A (Step 3C₅). Thereafter, the processes from Step 3C₂ to Step 3C₅ are repeated until the difference between the current passing through the center portion 200A and the current passing through the periphery portion 200B falls within the predetermined range. On the other hand, when the difference between the current passing through the center portion 200A and the current passing through the periphery portion 200B is within the predetermined range, the supply pipe 35 is stopped to stop the center facing portion 25A (Step 3C₆). After the center facing portion 25A is stopped, the voltage application is stopped (Step 3C₇). With this process, the plating of the dummy wafer 200 is finished.

After the plating of the dummy wafer 200 is finished, the holder vessel 5 moves up to a transfer position (I). After the holder vessel 5 is positioned at the transfer position (I), the pressing member 14 moves up to release the pressing to the dummy wafer 200. Thereafter, the suction pad 13 moves up to have the dummy wafer 200 apart from the seal member 12. With this process, the holding of the dummy wafer 200 by the holder 4 is released (Step 4c).

After the holding of the dummy wafer 200 is released, the carrier arm receives the dummy wafer 200. Thereafter, the carrier arm holding the wafer 100 contracts to carry the dummy wafer 200 out of the electrolytic plating apparatus 1 (Step 5c).

After the dummy wafer 200 is carried out of the electrolytic plating apparatus 1, a not-shown carrier arm holding a wafer 100 extends into the holder vessel 5 to carry the wafer 100 into the electrolytic plating apparatus 1 (Step 6c).

After the wafer 100 is carried into the electrolytic plating apparatus 1, the wafer 100 is suction-held by the suction pad 13. Subsequently, the suction pad 13 moves down to place the wafer 100 on the seal member 12. Thereafter, the pressing member 14 moves down to press the wafer 100 against the seal member 12. With this process, the wafer 100 is held by the holder 4 (Step 7C).

After the wafer 100 is held by the holder 4, the holder vessel 5 moves down to the plating position (IV), so that the wafer 100 is immersed in the plating solution. After the holder vessel 5 is positioned at the plating position (IV), the wafer 100 is plated while the center facing portion 25A is fixed at an adjusted position as shown in FIG. 14 (Step 8C).

After the plating of the wafer 100 is finished, the holder vessel 5 moves up to a spin-dry position (III). After the holder vessel 5 is positioned at the spin-dry position (III), the holder vessel 5 is rotated in a substantially horizontal plane for spin dry (Step 9C).

After the spin dry is finished, the holder vessel 5 moves up to a cleaning position (II). After the holder vessel 5 is positioned at the cleaning position (II), the holder vessel 5 is rotated in a substantially horizontal plane and pure water is sprayed to the wafer 100 from a washing nozzle 23 to clean the plating applied on the wafer 100 (Step 10c).

After the plating is cleaned, the holder vessel 5 moves down to the spin-dry position (III). After the holder vessel 5 is positioned at the spin-dry position (III), the holder vessel 5 is rotated in a substantially horizontal plane for spin dry (Step 11C).

After the spin dry is finished, the holder vessel 5 moves up to the transfer position (I). After the holder vessel 5 is positioned at the transfer position (I), the pressing member 14 moves up to release the pressing to the wafer 100. Thereafter, the suction pad 13 moves up to have the wafer 100 apart from the seal member 12. With this process, the holding of the wafer 100 by the holder 4 is released (Step 12C).

After the holding of the wafer 100 is released, the carrier arm receives the wafer 100. Thereafter, the carrier arm holding the wafer 100 contracts to carry the wafer 100 out of the electrolytic plating apparatus.1 (Step 13C).

It should be noted that the present invention is not to be limited to the contents described in the above embodiments, and appropriate changes in the structure, the materials, the arrangement of each member, and so on may be made within a range not departing from the sprit of the present invention. In the first to third embodiments described above, the supply pipe 35 is extended/contracted to vertically move the center facing portion 25A, but the vertical movement of the center facing portion 25A may be made without the extension/contraction of the supply pipe 35.

In the first to third embodiments described above, the periphery facing portion 25B is not moved and the center facing portion 25A is moved, but the periphery facing portion 25B may be moved without moving the center facing portion 25A. Further, the frame 26 whose center portion is positioned closer to the wafer 100 side than the periphery portion thereof is used, but a flat frame 26 may be used. Note that, when the flat frame 26 is used, the diaphragm 25 is flatly supported.

In the first to third embodiments described above, the controller 39 automatically controls the operation of the supply pipe extending/contracting mechanism 38, but the supply pipe extending/contracting mechanism 38 may be manually controlled. Further, the wafer 100 is used, but a glass substrate may be used.

### INDUSTRIAL APPLICABILITY

A solution treatment apparatus and a solution treatment method according to the present invention are usable in the semiconductor manufacturing industry.

What is claimed is:

1. A solution treatment apparatus, comprising:
a treatment solution tank configured to store a treatment solution in which a substrate is to be immersed;
a first electrode in electrical contact with the substrate immersed in the treatment solution;
a second electrode disposed in said treatment solution tank, a voltage being applied between said second electrode and said first electrode;
a diaphragm disposed between the substrate and said second electrode; and
a diaphragm position varying mechanism configured to partly vary a position of said diaphragm.

2. A solution treatment apparatus as set forth in claim 1, wherein, in a state before the position of said diaphragm is partly varied, a portion of said diaphragm facing a center portion of the substrate is positioned closer to a substrate side than a portion of said diaphragm facing a periphery portion of the substrate.

3. A solution treatment apparatus as set forth in claim 1, wherein said diaphragm position adjusting mechanism moves a portion of said diaphragm facing a center portion of the substrate.

4. A solution treatment apparatus as set forth in claim 1, further comprising a controller configured to control said diaphragm position varying mechanism.

5. A solution treatment apparatus as set forth in claim 4, further comprising a sensor configured to partly measure a degree of solution treatment applied on the substrate,
wherein said controller controls said diaphragm position varying mechanism based on a result of the measurement by said sensor.

6. A solution treatment apparatus as set forth in claim 4, further comprising:
a measurement substrate having a plurality of electrodes; and
an ammeter configured to measure a current passing through each of the electrodes, wherein said controller controls said diaphragm position varying mechanism based on a result of the measurement by said ammeter.

7. A solution treatment apparatus, comprising:
a treatment solution tank configured to store a treatment solution in which a substrate is to be immersed;
a first electrode in electrical contact with the substrate immersed in the treatment solution; a second electrode disposed in said treatment solution tank, a voltage being applied between said first electrode and said second electrode; and
a diaphragm disposed between the substrate and said second electrode, a portion of said diaphragm facing a center portion of the substrate being positioned closer to a substrate side than a portion of said diaphragm facing a periphery portion of the substrate.

8. A solution treatment method, comprising:
immersing a substrate in a treatment solution in a treatment solution tank and passing a current through the immersed substrate to apply solution treatment on the substrate; and
partly measuring a degree of the solution treatment applied on the substrate while the solution treatment is being applied on the substrate, and partly varying a position of a diaphragm disposed in the treatment solution tank based on a result of the measurement, to adjust the degree of the solution treatment in the substrate.

9. A solution treatment method, comprising:
immersing a measurement substrate having a plurality of electrodes in a treatment solution in a treatment solution tank and passing a current through each of the electrodes of the immersed measurement substrate to apply solution treatment on the measurement substrate while measuring the current passing through each of the electrodes;
immersing a substrate in the treatment solution in the treatment solution tank and passing a current through the immersed substrate to apply solution treatment on the substrate; and
partly varying a position of a diaphragm disposed in the treatment solution tank based on a result of the measurement while the solution treatment is being applied on the substrate, to adjust a degree of the solution treatment in the substrate.
